(19) United States
(12) Patent Application Publication
(10) Pub. No.: US 2024/0170921 A1
(43) Pub. Date: May 23, 2024

(54) LIGHT EMITTING ELEMENT, ILLUMINATION DEVICE, AND DISTANCE MEASURING DEVICE

(71) Applicant: SONY SEMICONDUCTOR SOLUTIONS CORPORATION, KANAGAWA (JP)

(72) Inventors: TAKASHI KOBAYASHI, KANAGAWA (JP); SHINICHI AGATUMA, KUMAMOTO (JP); MOTOI KIMURA, KANAGAWA (JP); TATSUYA OIWA, KANAGAWA (JP)

(21) Appl. No.: 18/551,490

(22) PCT Filed: Feb. 15, 2022
(86) PCT No.: PCT/JP2022/005917

§ 371 Date: Sep. 20, 2023

(30) Foreign Application Priority Data
Mar. 31, 2021 (JP) 2021-060075

(51) Int. Cl. H01S 5/183; G01S 7/481; H01S 5/40

(52) U.S. Cl. CPC H01S 5/18361; G01S 7/4815; H01S 5/40

(57) ABSTRACT

For example, a light emitting element capable of increasing a speed at which light emission of light emission units is switched is provided. The light emitting element includes: a conductive substrate having a first main surface and a second main surface opposite to the first main surface; a first electrode provided on the first main surface of the conductive substrate; a first DBR layer provided on a side of the second main surface of the conductive substrate and having a first main surface; at least two light emission units provided on a side opposite to the first main surface of the first DBR layer, in which a tunnel junction layer is provided between the second main surface of the conductive substrate and the first main surface of the first DBR layer, and each of the light emission units is separated from each other; a second DBR layer laminated on the first DBR layer and having a first main surface and a second main surface opposite to the first main surface; and a second electrode provided on a side of the second main surface of the second DBR layer.

### TECHNICAL FIELD

The present technology relates to a light emitting element, an illumination device, and a distance measuring device.

### BACKGROUND ART

There have been proposed various distance measuring methods (for example, the time of flight (TOF) method) for measuring a distance to a measuring target object by irradiating the measuring target object with light emitted from a plurality of light emission units and receiving reflected light from the measuring target object.

Incidentally, in a vertical cavity surface emitting laser (VCSEL) (see, for example, Patent Document 1) using GaAs, InP, or the like as a substrate, an n-type buffer layer (n-type distributed Bragg reflector (DBR) layer), an active layer, and a p-type DBR layer are formed on an n-type substrate, a cathode electrode is provided from a lower surface of the substrate, and an anode electrode is provided from an upper surface of an emitter, and it is common that all emitters simultaneously emit light. In addition, an n-type transistor is used as the drive element for causing the emitter to emit light in order to realize high-speed pulse light emission, and the drive element is disposed between the cathode on the lower surface of the substrate and the ground.

### CITATION LIST

### Patent Document

Patent Document 1: Japanese Patent Application Laid-Open No. 2011-61083

### SUMMARY OF THE INVENTION

### Problems to be Solved by the Invention

However, in the general configuration described above, since it is necessary to arrange the same number of integrated circuits (ICs) for controlling light emission switching as the number of divisions between the power supply VCC and the anode electrode in order to switch light emission, this leads to an increase in size and cost of the device. Therefore, it is difficult to greatly increase the number of divisions. In addition, the light emission switching speed is limited in terms of IC performance.

An object of the present technology is to provide a novel and useful light emitting element, an illumination device, and a distance measuring device that solve such a problem.

### Solutions to Problems

The present technology is a light emitting element including:
a conductive substrate having a first main surface and a second main surface opposite to the first main surface;
a first electrode provided on the first main surface of the conductive substrate;
a first DBR layer provided on a side of the second main surface of the conductive substrate and having a first main surface;
at least two light emission units provided on a side opposite to the first main surface of the first DBR layer,
in which a tunnel junction layer is provided between the second main surface of the conductive substrate and the first main surface of the first DBR layer, and
each of the light emission units is separated from each other;
a second DBR layer laminated on the first DBR layer and having a first main surface and a second main surface opposite to the first main surface; and
a second electrode provided on a side of the second main surface of the second DBR layer.

Further, the present disclosure is a light emitting element including:
a conductive substrate having a first main surface and a second main surface opposite to the first main surface;
a first electrode provided on the first main surface of the conductive substrate;
a first n-type DBR layer provided on a side of the second main surface of the conductive substrate and having a first main surface;
at least two light emission units provided on an opposite side to the first main surface of the first n-type DBR layer, each of the light emission units being separated from each other;
a second n-type DBR layer having a first main surface and a second main surface opposite to the first main surface;
a tunnel junction layer; and
a second electrode provided on a side of the second main surface of the n-type DBR layer,
in which the tunnel junction layer is provided between the opposite side of the first n-type DBR layer and the second main surface of the second n-type DBR layer.

Further, the present technology is an illumination device including:
the light emitting element described above;
a holding unit that holds the light emitting element; and
an optical unit that converts a light beam emitted from the light emitting element into a predetermined pattern.

Further, the present technology is a distance measuring device including:
the illumination device described above;
a control unit that controls the illumination device;
a light receiving unit that receives reflected light reflected from a target object; and
a distance measuring unit that calculates a distance measurement distance from image data obtained by the light receiving unit.

### BRIEF DESCRIPTION OF DRAWINGS

FIG. 1 is a schematic cross-sectional view illustrating an example of a schematic configuration of an illumination device according to an embodiment.

FIG. 2 is a block diagram illustrating an example of a schematic configuration of a distance measuring device including an illumination device.

FIG. 3A is a diagram illustrating an example of an irradiation pattern at the time of spot irradiation of the illumination device, and FIG. 3B is an enlarged view in a frame of a chain line in FIG. 3A.

FIG. 4A is a diagram illustrating another example of an irradiation pattern at the time of spot irradiation of the illumination device, and FIG. 4B is an enlarged view in a frame of a chain line in FIG. 4A.

FIG. 5 is a schematic view illustrating an example of a diffraction element.

FIG. 6A is a schematic view illustrating an irradiation pattern before spot irradiation light emitted from a set of light emission units passes through a diffraction element, and FIG. 6B is a schematic view illustrating an irradiation pattern after the spot irradiation light emitted from the set of light emission units passes through the diffraction element.

FIG. 7 is a schematic cross-sectional view illustrating an example of a light emitting element in an embodiment.

FIG. 8 is a schematic view illustrating an example of a planar configuration of a light emitting element.

FIG. 9 is a diagram illustrating an example of a configuration of a drive circuit of the illumination device.

FIG. 10 is a diagram for explaining a light emission sequence of the illumination device.

FIG. 11 is a schematic cross-sectional view illustrating an example of a light emitting element in a modification.

FIG. 12 is a schematic cross-sectional view illustrating another example of the light emitting element in a modification.

FIG. 13 is a schematic cross-sectional view illustrating another example of the light emitting element in a modification.

FIG. 14 is a schematic cross-sectional view illustrating an example of a schematic configuration of an illumination device in a modification.

FIG. 15A is a schematic plan view illustrating an example of a configuration of a microlens array in a modification, and FIG. 15B is a schematic view illustrating an example of a cross-sectional configuration of the microlens array in FIG. 15A.

FIG. 16A is a schematic view illustrating a position of a light emission unit for spot irradiation with respect to the microlens array illustrated in FIG. 15A, and FIG. 16B is a schematic view illustrating a position of a light emission unit for uniform irradiation with respect to the microlens array illustrated in FIG. 15A.

FIG. 17 is a diagram for explaining a beam forming function in a modification.

FIG. 18 is a diagram illustrating an irradiation pattern for a target object in a modification.

FIG. 19A is a diagram illustrating an irradiation position of light emitted from a light emission unit for spot irradiation toward a target object and transmitted without being diffracted by a diffraction element, FIG. 19B is a diagram illustrating an example of an irradiation position of light emitted from the light emission unit for spot irradiation and diffracted by the diffraction element, and FIG. 19C is a diagram illustrating an example of an irradiation position of light emitted from a light emission unit for uniform irradiation and diffracted by the diffraction element.

FIG. 20 is a diagram illustrating an example of an irradiation pattern at the time of spot irradiation of the illumination device.

FIG. 21 is a diagram illustrating an example of an irradiation pattern at the time of uniform irradiation of the illumination device.

FIG. 22 is a diagram illustrating a first example of grouping of light emitting elements according to a modification.

FIG. 23 is a diagram illustrating a second example of grouping of light emitting elements according to a modification.

FIG. 24 is a diagram illustrating a third example of grouping of light emitting elements according to a modification.

FIG. 25 is a diagram illustrating a fourth example of grouping of light emitting elements according to a modification.

FIG. 26 is a diagram illustrating an example of a top view of a semiconductor laser driving apparatus in an application example.

FIG. 27 is a diagram illustrating an example of a cross-sectional view of a semiconductor laser driving apparatus in an application example.

FIG. 28 is a diagram illustrating another example of the cross-sectional view of the semiconductor laser driving apparatus in the application example.

### MODE FOR CARRYING OUT THE INVENTION

Hereinafter, embodiments and the like of the present technology will be described with reference to the drawings. Note that description will be given in the following order.
<1. Embodiment>
<2. Modification>
<3. Application Example>

### 1. Embodiment

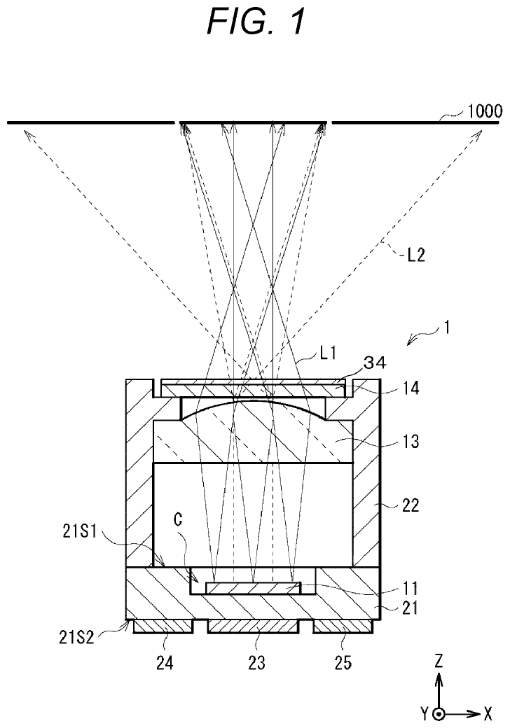

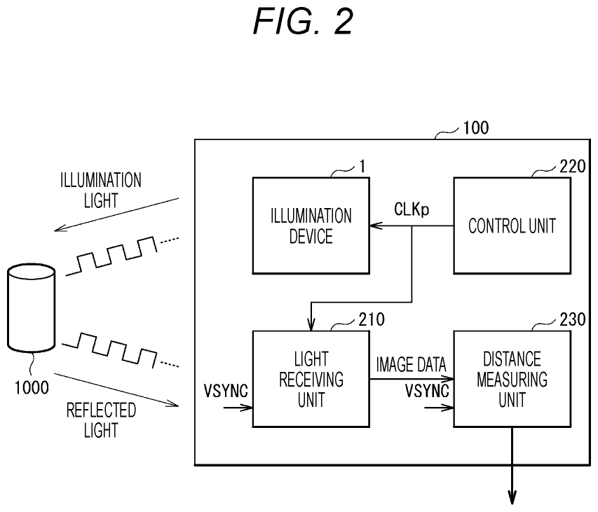

FIG. 1 is a cross-sectional view schematically illustrating an example of a schematic configuration of an illumination device (illumination device 1) according to an embodiment of the present technology. FIG. 2 is a block diagram illustrating a schematic configuration of a distance measuring device (distance measuring device 100) including the illumination device 1 illustrated in FIG. 1. The distance measuring device 100 includes the illumination device 1, a control unit 220 that controls the illumination device 1, a light receiving unit 210 that receives reflected light reflected from a distance measuring target object, and a distance measuring unit 230 that calculates a distance measurement distance from image data obtained by the light receiving unit 210.

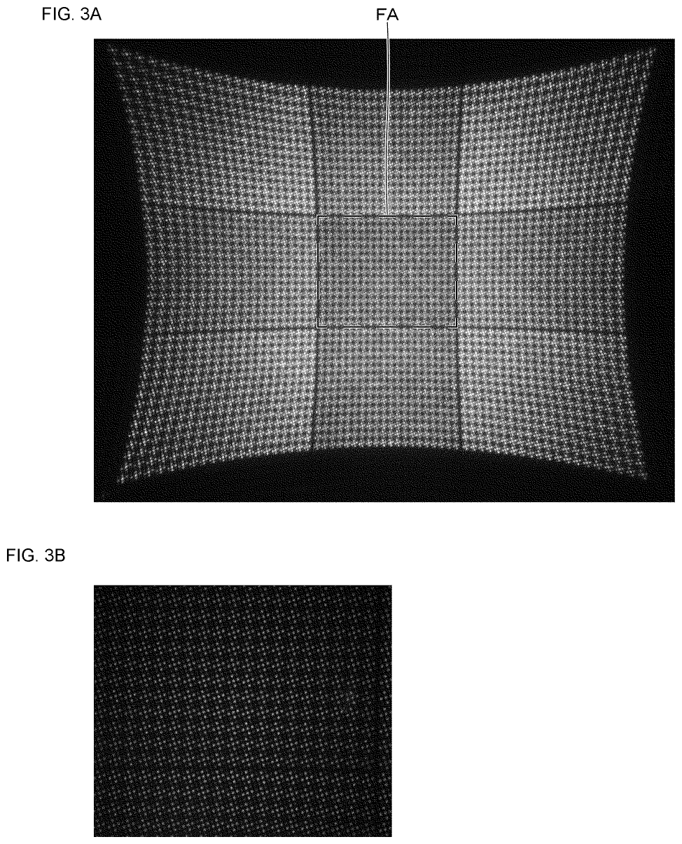

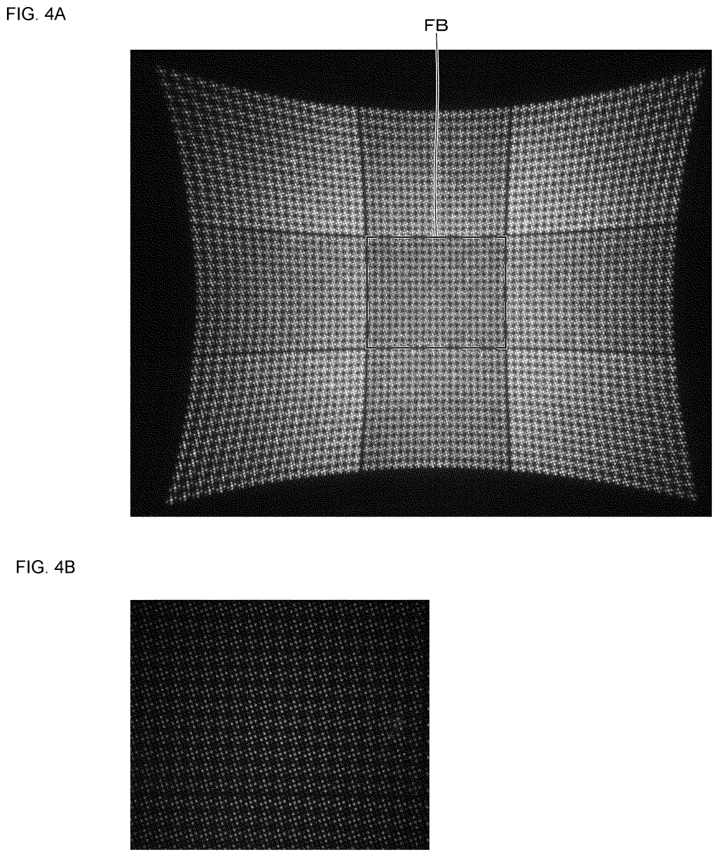

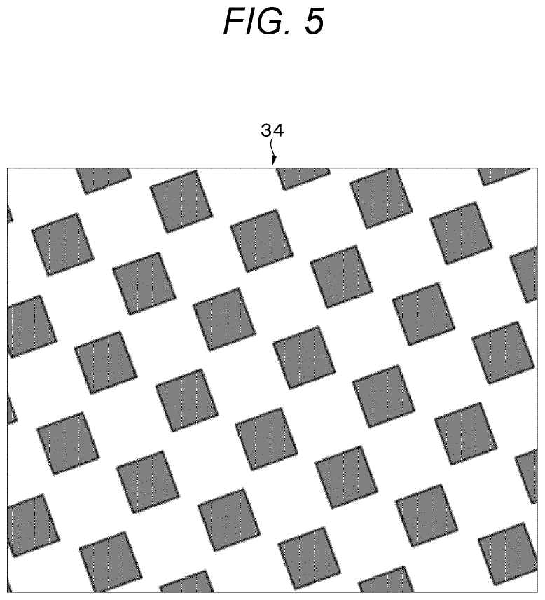

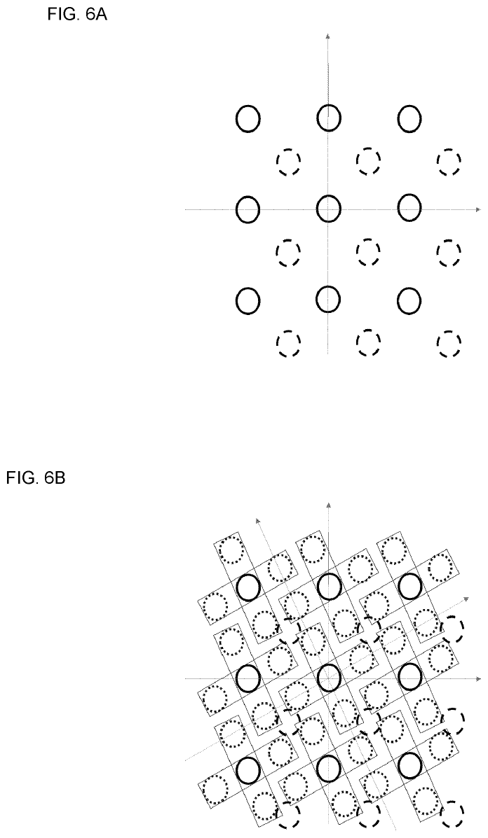

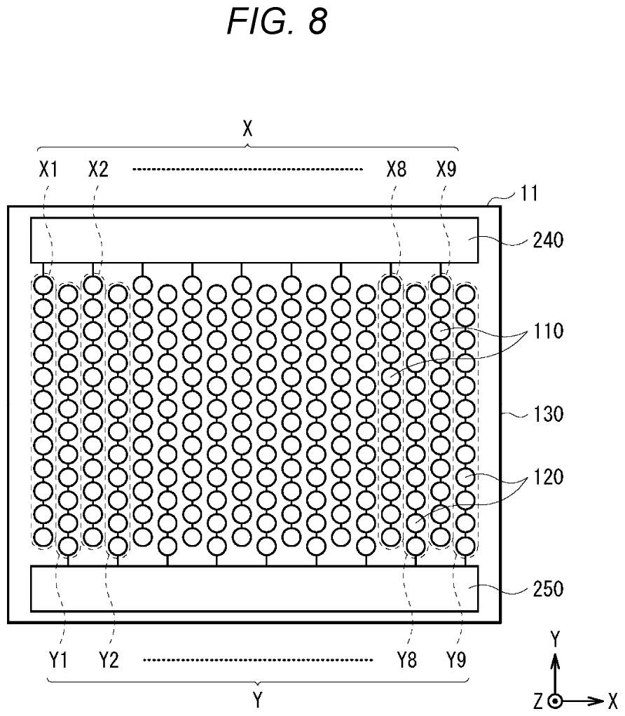

In the illumination device 1 according to the embodiment, the light L1 and the light L2 emitted from a light emitting element 11 including a plurality of light emission units (for example, light emission units 110 and 120 illustrated in FIG. 8) are, for example, light emitted with spots by shaping a beam shape. A diffraction element 14 is an optical element that tiles light L1 and light L2 to widen the irradiation range, and for example, tiles light L1 and light L2 into 3×3 to widen the irradiation range. FIGS. 3 and 4 each illustrate irradiation patterns of two sets of light emission units 110 and 120. The irradiation range of the light L1 is a range within the chain line FA (or the chain line FB illustrated in FIG. 4A) illustrated in FIG. 3A, and the irradiation range of the light L2 is a range around the range within the chain line FA (or the chain line FB illustrated in FIG. 4A) illustrated in FIG. 3A. Each spot of the light L1 and L2 diffracted by the diffraction element 14 is further divided (for example, five divisions) by a diffraction element 34. As the diffraction element 34, a diffractive optical element (DOE) illustrated in FIG. 5 in which a fine lattice shape is formed on a plane of glass or the like can be used. The diffraction element 34 divides spot irradiation (circle indicated by solid line in FIG. 6A) by one light emission unit illustrated in FIG. 6A into five so as to fill a space between spot irradiation as illustrated in FIG. 6B by generating diffracted light in two directions for each spot.

### [Configuration of Illumination Device]

The illumination device 1 includes, for example, the light emitting element 11, a collimator lens 13, and the diffraction element 14. The collimator lens 13, the diffraction element 14, and the diffraction element 34 are disposed, for example, in this order on an optical path of light (light L1 and L2) emitted from the light emitting element 11. The light emitting element 11 is held by, for example, a holding unit 21, and the collimator lens 13, the diffraction element 14, and the diffraction element 34 are held by, for example, a holding unit 22. The holding unit 21 includes, for example, one anode electrode unit 23 and two cathode electrode units 24 and 25 on a surface 21S2 opposite to a surface 21S1 holding the light emitting element 11. Hereinafter, each member constituting the illumination device 1 will be described in detail.

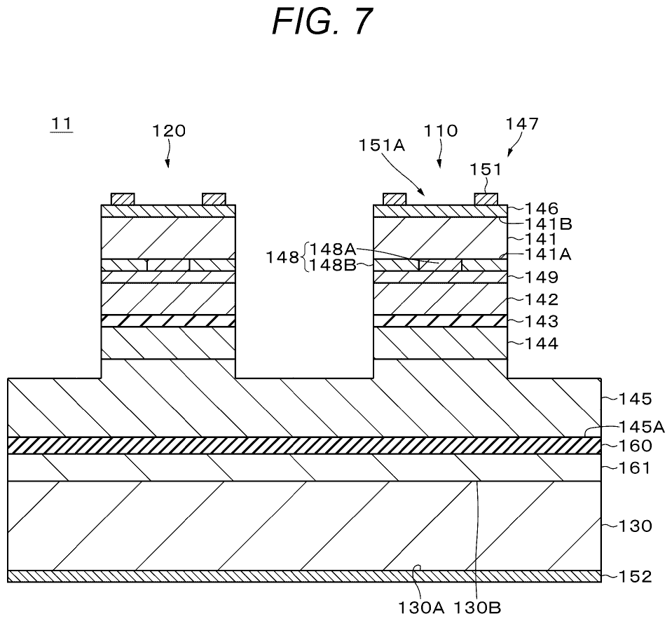

The light emitting element 11 is, for example, a surface emitting type surface emitting semiconductor laser. FIG. 7 schematically illustrates an example of a cross-sectional configuration of a light emission unit (light emission units 110 and 120) of the light emitting element 11. Each of the light emission units 110 and 120 emits light for spot irradiation. Note that, although two light emission units (light emission units 110 and 120) are illustrated in FIG. 7, the number of light emission units only needs to be at least two. Furthermore, the description of the light emission unit 110 can also be applied to the light emission unit 120 unless otherwise specified.

The light emitting element 11 schematically includes an n-type substrate 130 having a main surface 130A as an example of a first main surface and a main surface 130B as a main surface (second main surface) opposite to the first main surface, a lower electrode 152 (an example of a first electrode) provided on the main surface 130A of the n-type substrate 130, a p-type DBR layer (an example of a first DBR layer) 145 provided on the main surface 130B side of the n-type substrate 130 and having a main surface 145A, and at least two light emission units (for example, the light emission units 110 and 120) provided on the side opposite to the main surface 145A of the p-type DBR layer 145.

In addition, a tunnel junction layer 160 is provided between the main surface 130B of the n-type substrate and the main surface 145A of the p-type DBR layer 145. Note that the term “between” only needs to be provided therebetween, and does not necessarily need to be in contact. In addition, the term “side” only needs to exist in the direction, and does not necessarily need to be in contact. The light emission unit 110 is laminated on the p-type DBR layer 145 and includes an n-type DBR layer (an example of a second DBR layer) 141 having a main surface 141A and a main surface 141B opposite to the main surface 141A, and an upper electrode 151 (an example of a second electrode) provided on the main surface 141B side of the n-type DBR layer 141.

More specifically, an n-type buffer layer 161 is provided between the main surface 130A of the n-type substrate 130 and the tunnel junction layer 160. In addition, the light emission unit 110 has a configuration in which a p-type spacer layer 144, an active layer 143, an n-type spacer layer 142, an n-type buffer layer 149, a current confinement layer 148, an n-type DBR layer 141, and an n-type contact layer 146 are sequentially laminated from the side opposite to the main surface 145A of the p-type DBR layer 145, and this configuration (hereinafter, also referred to as a semiconductor layer as appropriate) is a columnar mesa portion 147. The upper electrode 151 is attached to the n-type contact layer 146. Hereinafter, details of each configuration will be described.

The n-type substrate 130 is, for example, an n-type GaAs substrate. Examples of an n-type impurity include, for example, silicon (Si), selenium (Se) or the like. The semiconductor layers are each constituted by, for example, an AlGaAs-based compound semiconductor. The AlGaAs-based compound semiconductor refers to a compound semiconductor containing at least aluminum (Al) and gallium (Ga) among Group 13 elements in the periodic table of elements and at least arsenic (As) among Group 15 elements in the periodic table of elements.

The n-type DBR layer 141 is formed by alternately laminating a low refractive index layer and a high refractive index layer (both not illustrated). The low refractive index layer is constituted by, for example, n-type AlxiGa₁₋ₓ₁As (0<x1<1) having a thickness of λ₀/4n₁ (λ₀ represents an emission wavelength, and n₁ represents a refractive index). The high refractive index layer is constituted by, for example, n-type Alₓ₂Ga₁₋ₓ₂As (0<x2<x1) having a thickness of λ₀/4n₂ (n2 is a refractive index).

The n-type spacer layer 142 is constituted by, for example, n-type Alₓ₃Ga₁₋ₓ₃As (0<x3<1). The p-type spacer layer 144 is constituted by, for example, p-type Al_{z5}Ga₁₋ₓ₅As (0<x5<1). Examples of the p-type impurity include zinc (Zn), magnesium (Mg), and beryllium (Be).

The active layer 143 has a multi quantum well structure (MQW). The active layer 143 has, for example, a structure in which a thin film of n-type Alₓ₆Ga₁₋ₓ₆As (0<x6<1) and a tunnel junction layer are alternately laminated.

The p-type DBR layer 145 is formed by alternately laminating a low refractive index layer and a high refractive index layer (both not illustrated). The low refractive index layer is constituted by, for example, p-type Alₓ₈Ga₁₋ₓ₈As (0<x8<1) having a thickness of λ₀/4n₃ (n₃ is a refractive index). The high refractive index layer is constituted by, for example, p-type Alₓ₉Ga₁₋ₓ₉As (0<x9<x8) having a thickness of λ₀/4n₄ (n₄ is a refractive index). The contact layer 16 is constituted by, for example, p-type Alₓ₁₀Ga₁₋ₓ₁₀As (0<x10<1).

The current confinement layer 148 and the n-type buffer layer 149 are provided in the n-type DBR layer 141, for example. The current confinement layer 148 is formed at a position away from the active layer 143 in relation to the n-type buffer layer 149. The current confinement layer 148 is provided, for example, in place of the low refractive index layer in a portion of the low refractive index layer that is, for example, several layers away from the active layer 143 side in the n-type DBR layer 141. The current confinement layer 148 has a current injection region 148A and a current confinement region 148B. The current injection region 148A is formed in a central region in the plane. The current confinement region 148B is formed in a peripheral edge of the current injection region 148A, that is, an outer edge region of the current confinement layer 148, and has an annular shape.

The current injection region 148A is constituted by, for example, n-type Alₓ₁₁Ga₁₋ₓ₁₁As (0.98≤x11≤1). The current confinement region 148B is constituted by, for example, aluminum oxide (Al₂O₃), and is obtained by oxidizing an oxidized layer (not illustrated) constituted by, for example, n-type Alₓ₁₁Ga₁₋ₓ₁₁As from the side surface of the mesa portion 147. As a result, the current confinement layer 148 has a function of constricting the current.

The n-type buffer layer 149 is formed closer to the active layer 143 in relation to the current confinement layer 148. The n-type buffer layer 149 is formed adjacent to the current confinement layer 148. For example, as illustrated in FIG. 7, the n-type buffer layer 149 is formed in contact with a surface (lower surface) of the current confinement layer 148 on the active layer 143 side. Note that a thin layer having a thickness of, for example, about several nm may be provided between the current confinement layer 148 and the n-type buffer layer 149. The n-type buffer layer 149 is provided, for example, in place of the high refractive index layer in a portion of the high refractive index layer that is, for example, several layers away from the current confinement layer 148 in the n-type DBR layer 141.

The n-type buffer layer 149 has an unoxidized region and an oxidized region (both not illustrated). The unoxidized region is mainly formed in a central region in the plane, and is formed, for example, at a portion in contact with the current injection region 148A. The oxidized region is formed on a peripheral edge of the unoxidized region and has an annular shape. The oxidized region is mainly formed in the outer edge region in the plane, and is formed, for example, in a portion in contact with the current confinement region 148B. The oxidized region is formed to be biased toward the current confinement layer 148 side in a portion other than the portion corresponding to the outer edge of the n-type buffer layer 149.

The unoxidized region is constituted by a semiconductor material containing Al, and is constituted by, for example, n-type Alₓ₁₂Ga₁₋ₓ₁₂As (0.85<x12≤0.98) or n-type InₐAlₓ₁₃Ga₁₋ₓ₁₃₋ₐAs (0.85<x13≥0.98). The oxidized region includes, for example, aluminum oxide (Al₂O₃), and is obtained by oxidizing a layer to be oxidized (not illustrated) including, for example, n-type Alₓ₁₂Ga₁₋ₓ₁₂As or n-type In_{b}Alₓ₁₃Ga_{1-x13-b}As from the side surface side and the layer to be oxidized side of the mesa portion 147. The layer to be oxidized of the n-type buffer layer 149 is constituted by a material and a thickness that have a higher oxidation rate than the p-type DBR layer 145 and the n-type DBR layer 141 and a lower oxidation rate than the layer to be oxidized of the current confinement layer 148.

The tunnel junction layer 160 is a substance through which a tunnel current flows during energization in this section, and is constituted by, for example, a highly doped n-type and p-type Alₓ₁₄Ga₁₋ₓ₁₄As (0<x14<1) thin film. The tunnel junction layer 160 may be any substance as long as a tunnel current flows therethrough as exemplified. The n-type buffer layer 161 is provided between the tunnel junction layer 160 and the n-type substrate 130. As the n-type buffer layer, a similar one to the n-type buffer layer 149 can be applied.

On the upper surface of the mesa portion 147 (the upper surface of the n-type contact layer 146), the annular upper electrode 151 having an opening (light emission port 151A) in a region facing at least the current injection region 148A is formed. In addition, an insulating layer (not illustrated) is formed on a side surface and a peripheral surface of the mesa portion 147. The upper electrode 151 is connected to the electrode pad 240 or the electrode pad 250 by wiring (not illustrated) for each of light emission unit groups X1 to X9 and light emission unit groups Y1 to Y9. For example, the electrode pad 240 or the electrode pad 250 is electrically connected by wire bonding. In addition, the lower electrode 152 is provided on the other surface of the n-type substrate 130. The lower electrode 152 is electrically connected to, for example, the anode electrode unit 23. As described above, the embodiment is an embodiment in which the anode electrode unit is a common electrode, and the cathode electrode unit is separately provided.

Here, the upper electrode 151 is formed by, for example, laminating titanium (Ti), platinum (Pt), and gold (Au) in this order, and is electrically connected to the n-type contact layer 146 above the mesa portion 147. The lower electrode 152 has a structure in which, for example, an alloy of gold (Au) and germanium (Ge), nickel (Ni), and gold (Au) are laminated in order from the n-type substrate 130 side, and is electrically connected to the n-type substrate 130.

The plurality of light emission units has a configuration in which, for example, a plurality of light emission units (a plurality of light emission units 110 for spot irradiation) used for spot irradiation and a plurality of light emission units (a plurality of light emission units 120 for spot irradiation) used for spot irradiation are arranged in an array on the n-type substrate 130. The plurality of light emission units 110 and the plurality of light emission units 120 are physically and electrically separated from each other by the mesa structure of the mesa portion 147.

The above-described light emitting element 11 has two mesa portions 147, but the distance measuring device 100 has a plurality of light emission units, for example, a plurality of light emission units 110 and a plurality of light emission units 120. Each of the plurality of light emission units 110 and 120 emits light for spot irradiation. The plurality of light emission units 110 and the plurality of light emission units 120 are electrically connected to each other. Specifically, for example, as illustrated in FIG. 8, the plurality of light emission units 110 constitutes a plurality of (for example, nine in FIG. 8) light emission unit groups X (light emission unit groups X1 to X9) including n (for example, 12 in FIG. 8) light emission units 110 extending in one direction (for example, in the Y-axis direction). Similarly, the plurality of light emission units 120 constitutes a plurality of (for example, nine in FIG. 8) light emission unit groups Y (light emission unit groups Y1 to Y9) including m (for example, 12 in FIG. 8) light emission units 120 extending in one direction (for example, in the Y-axis direction). As illustrated in FIG. 8, the light emission unit groups X1 to X9 and the light emission unit groups Y1 to Y9 are alternately arranged on the n-type substrate 130 having a rectangular shape, for example. The light emission unit groups X1 to X9 are electrically connected to, for example, the electrode pad 240 provided along one side of the n-type substrate 130, and the light emission unit groups Y1 to Y9 are electrically connected to, for example, the electrode pad 250 provided along another side facing the one side of the n-type substrate 130. Note that, although FIG. 8 illustrates an example in which the light emission unit groups X1 to X9 and Y1 to Y9 are alternately arranged, the present invention is not limited thereto. For example, the number of the plurality of light emission units 110 and the number of the plurality of light emission units 120 can be arbitrarily arranged depending on the number and position of desired light emission points and the amount of light output. As an example, the plurality of light emission units 120 may be arranged in every two rows of the plurality of light emission units 110.

The collimator lens 13 emits the laser beams L110 emitted from the plurality of light emission units 110 and the laser beams L120 emitted from the plurality of light emission units 120 as substantially parallel light. The collimator lens 13 is, for example, a lens for collimating the laser beam L110 and the laser beam L120 emitted from the light emission units 110 and 120 and coupling them with the diffraction elements 14 and 34. In the embodiment, both the laser beam L110 and the laser beam L120 are light to be spot-emitted.

The diffraction element 14 divides and emits each of the laser beams L110 emitted from the plurality of light emission units 110 and the laser beams L120 emitted from the plurality of light emission units 120. For example, the diffraction element 14 divides the laser beams L110 emitted from the plurality of light emission units 110 and the laser beams L120 emitted from the plurality of light emission units 120 into 3×3. By disposing the diffraction element 14, it is possible to tile the light fluxes of the laser beam L110 and the laser beam L120, for example, to increase the irradiation range. Furthermore, by arranging the diffraction element 34, each spot of the laser beams L110 and L120 to be spot-emitted can be divided into, for example, five, and the number of spots at the time of spot irradiation can be increased.

The holding unit 21 and the holding unit 22 are for holding the light emitting element 11, the collimator lens 13, and the diffraction element 14. Specifically, the holding unit 21 holds the light emitting element 11 in a recess C (see FIG. 1) provided on the upper surface (surface 21S1). The holding unit 22 holds the collimator lens 13 and the diffraction element 14. The holding unit 21 and the holding unit 22 are connected to each other such that the light L1 and the light L2 emitted from the light emitting element 11 are incident on the collimator lens 13, and the light L1 and the light L2 transmitted through the collimator lens 13 become substantially parallel light.

A plurality of electrode units is provided on the back surface (surface 21S2) of the holding unit 21. Specifically, the anode electrode unit 23 common to the plurality of light emission units 110 for spot irradiation and the plurality of light emission units 120 for spot irradiation, the cathode electrode unit 24 of the plurality of light emission units 110 for spot irradiation, and the cathode electrode unit 25 of the plurality of light emission units 120 for spot irradiation are provided on the surface 21S2 of the holding unit 21.

Note that the configuration of the plurality of electrode units provided on the surface 21S2 of the holding unit 21 is not limited to the above, and for example, the anode electrode units of the plurality of light emission units 110 for spot irradiation and the plurality of light emission units 120 for spot irradiation may be separately formed, or the anode electrode units of the plurality of light emission units 110 for spot irradiation and the plurality of light emission units 120 for spot irradiation may be formed as the common electrode unit. Further, the collimator lens 13 and the diffraction element 14 may be held by the holding unit 21.

### [Method for Driving Illumination Device]

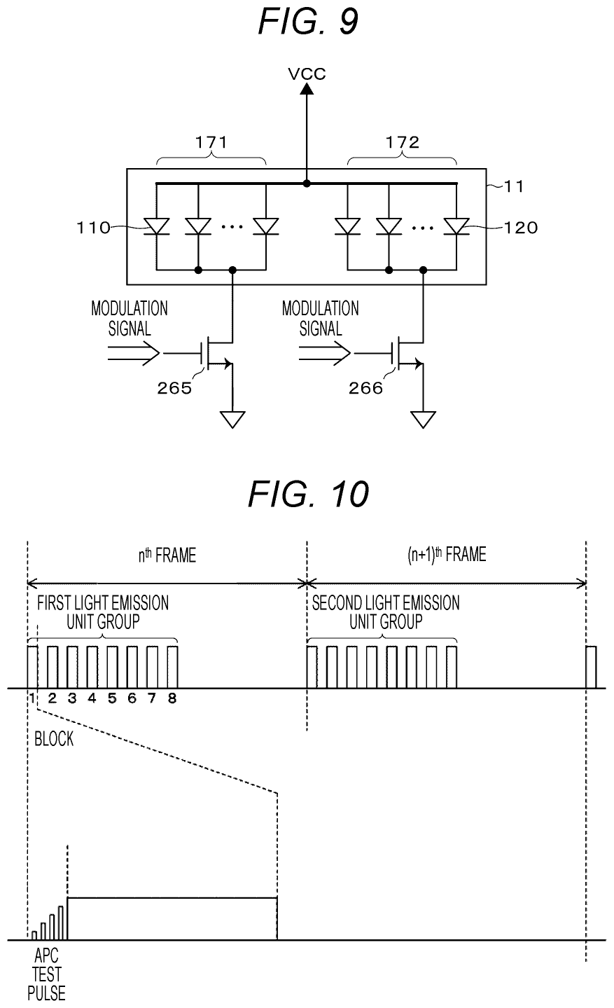

FIG. 9 illustrates an example of a configuration of a drive circuit of the illumination device 1. As illustrated in the drawing, anodes of a first light emission unit group 171 and a second light emission unit group 172 are connected to a power supply (VCC). In addition, a cathode of the first light emission unit group 171 is connected to a drive unit 265, and a cathode of the second light emission unit group 172 is connected to a drive unit 266. The first light emission unit group 171 is, for example, a set of light emission units 110 connected to the electrode pad 240. In addition, the second light emission unit group 172 is, for example, a set of light emission units 120 connected to the electrode pad 250.

As the drive unit 265 and the drive unit 266, an n-type metal oxide semiconductor field effect transistor (MOSFET) can be applied. When a modulation signal that defines the timing of ON/OFF modulation is supplied, each of the drive unit 265 and the drive unit 266 connects the ground and the first light emission unit group 171 or the second light emission unit group 172 at the ON timing. As a result, a current flows through the first light emission unit group 171 and the second light emission unit group 172 at the ON timing, and light emission occurs. Since the cathodes of the first light emission unit group 171 and the second light emission unit group 172 are completely separated, and the drive unit 265 and the drive unit 266 are provided, respectively, it is possible to drive the first light emission unit group 171 and the second light emission unit group 172 with different waveforms (timing and current).

Note that each of the drive unit 265 and the drive unit 266 may be a P-type MOSFET or a bipolar transistor.

FIG. 10 illustrates an example of a light emission sequence of the illumination device 1. A section in which one distance measurement image is generated is referred to as a “frame”, and one frame is set to, for example, a time of 33.3 msec (frequency of 30 Hz). As a distance measurement pulse, for example, a rectangular continuous wave of 100 MHz/Duty=50% is used, and this causes continuous light emission between accumulation sections. A plurality of the accumulation sections with different conditions can be provided in the frame. Although eight accumulation sections are illustrated in FIG. 10, the number of accumulation sections is not limited to this number.

As illustrated in the drawing, in the illumination device 1, the first light emission unit group 171 is caused to emit light in one frame, and the light receiving unit 210 (see FIG. 2) receives the reflected light and generates a distance measurement image. In the next frame, the second light emission unit group 172 is caused to emit light, and the light receiving unit 210 receives reflected light to generate a distance measurement image. Note that, in FIG. 10, the first light emission unit group 171 and the second light emission unit group 172 are switched in each frame, but may be switched in each plurality of frames. Note that light emission of the first light emission unit group 171 and the second light emission unit group 172 may be switched, for example, in units of one frame, in units of blocks, or in units of a plurality of blocks. Therefore, for example, it is possible to switch between two sets of spot irradiation at a faster speed as compared with a method of mechanically switching focal positions of laser beams emitted from a plurality of the light emission units.

### Effects Obtained by Present Embodiment

According to the present embodiment, it is not necessary to provide a switching IC for switching light emission of the light emission units between the power supply and the anode electrode. In addition, since it is not necessary to provide the switching IC, there is no restriction on the switching speed of the light emission units depending on the performance of the switching IC, and switching can be performed at high speed. In addition, the emitter interval can be further reduced as compared with a configuration in which the anode electrode and the cathode electrode are formed on the same plane. In addition, in the configuration in which the anode electrode and the cathode electrode are formed on the same plane, the resistance in the VCSEL is large and the voltage increases, or it is necessary to route the wiring to the anode electrode and the cathode electrode on the same plane, which increases the wiring inductance. However, in the present embodiment, since the anode electrode and the cathode electrode are formed on different planes, such inconvenience is not caused.

### 2. Modification

Although the embodiment of the present disclosure has been specifically described above, the contents of the present disclosure are not limited to the embodiment described above, and various modifications based on the technical idea of the present disclosure are possible. Hereinafter, each of a plurality of modifications will be described. Note that configurations identical or similar to those of the embodiment are denoted by the same reference numerals, and redundant description will be omitted as appropriate.

### [Modification 1]

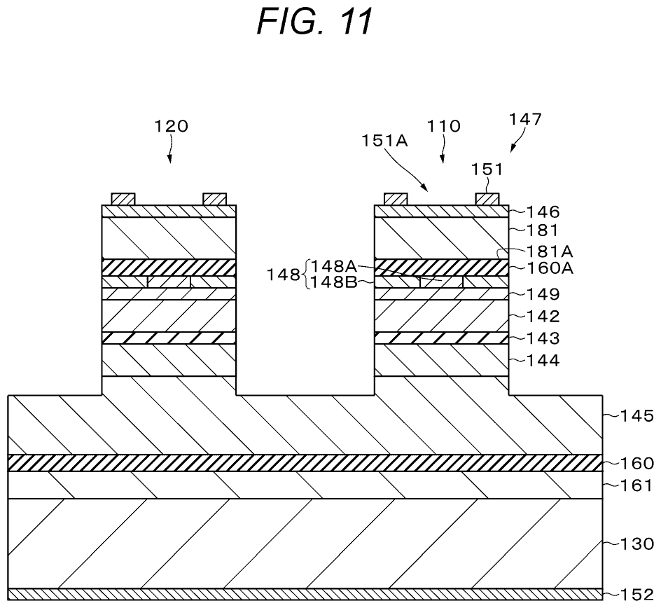

In the embodiment, the second DBR layer has been described as the n-type DBR layer 141, but as illustrated in FIG. 11, the second DBR layer may be a p-type DBR layer 181. In this case, for example, a tunnel junction layer 160A as another tunnel junction layer different from the tunnel junction layer 160 may be provided between a main surface 181A as the first main surface of the p-type DBR layer 1801 and the p-type DBR layer 145.

### [Modification 2]

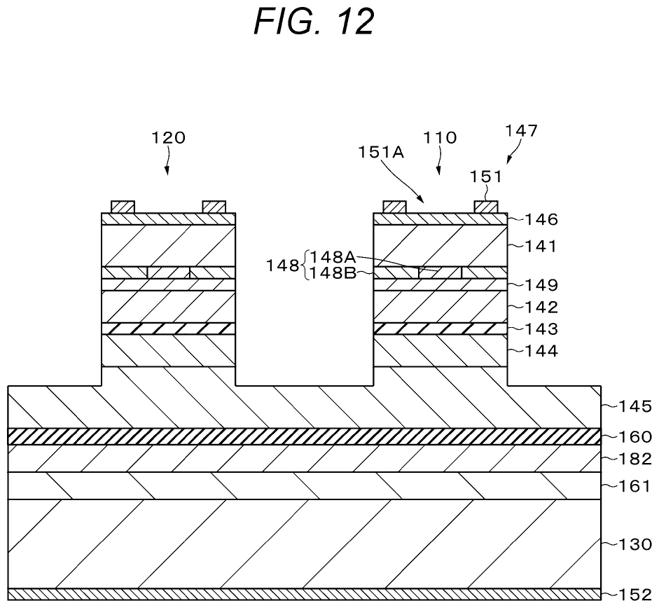

Furthermore, as illustrated in FIG. 12, an n-type DBR layer 182 may be provided between the tunnel junction layer 160 and the n-type substrate 130 (specifically, the n-type buffer layer 161).

### [Modification 3]

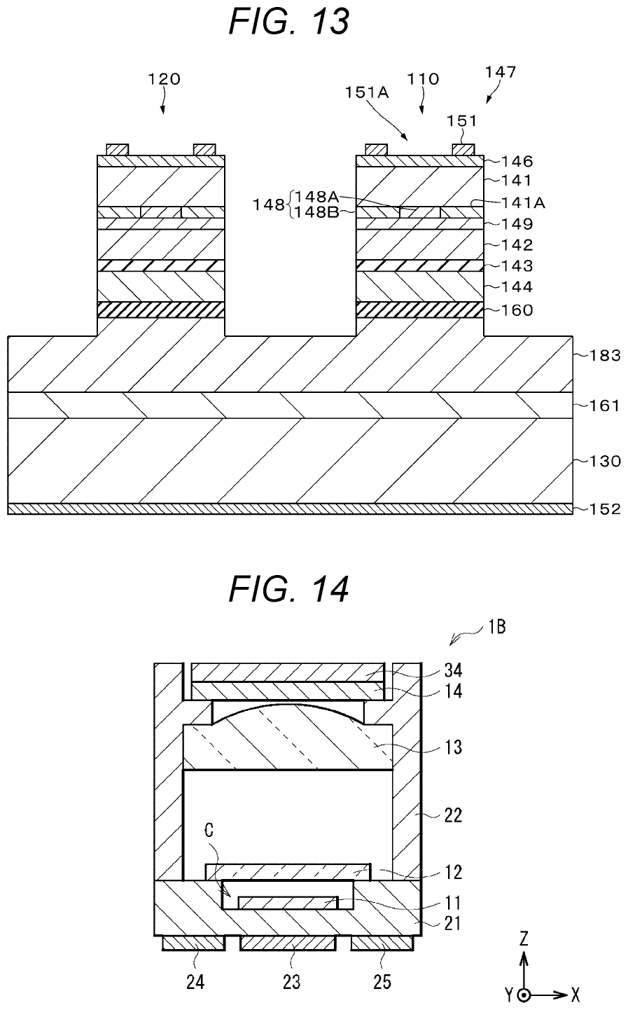

Furthermore, as illustrated in FIG. 13, the p-type DBR layer 145 described in the embodiment may be configured as an n-type DBR layer 183. In such a configuration, for example, the n-type DBR layer 141 corresponds to a first n-type DBR layer, and the n-type DBR layer 183 corresponds to a second n-type DBR layer. Then, the tunnel junction layer 160 may be provided between the main surface 141A of the n-type DBR layer 141 and the n-type DBR layer 183, specifically, between the n-type DBR layer 183 and the p-type spacer layer 144.

### [Modification 4]

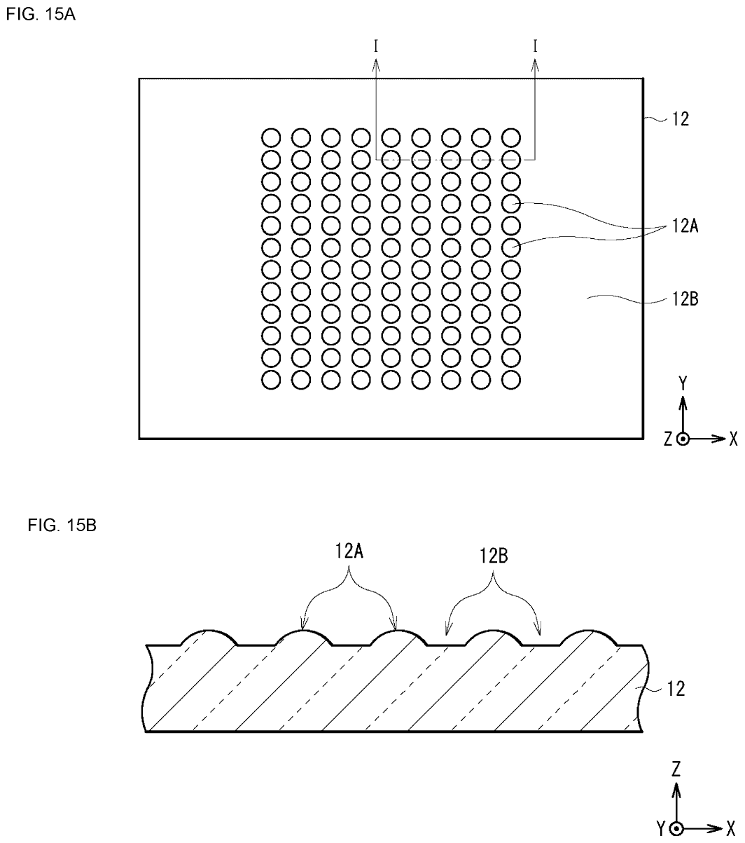

FIG. 14 is a cross-sectional view schematically illustrating an example of a schematic configuration of an illumination device (illumination device 1B) according to Modification 4 of the present technology. The illumination device 1B of the present modification is different from the above-described embodiment in that the microlens array 12 (an example of a second optical member) is disposed on a preceding stage of the collimator lens 13 (an example of a first optical member), for example, on optical paths of laser beams L110 and laser beams L120 respectively emitted from the plurality of light emission units 110 and the plurality of light emission units 120. In Modification 4, the laser beam L110 is light to be spot-emitted, and the laser beam L120 is light to be uniformly emitted.

For example, the microlens array 12 forms a shape of at least one beam of light (laser beam L110 or laser beam L120) emitted from the plurality of the light emission units 110 for spot irradiation and the plurality of the light emission units 120 for uniform irradiation and emits the beam. FIG. 15A schematically illustrates an example of a planar configuration of the microlens array 12, and FIG. 15B schematically illustrates a cross-sectional configuration of the microlens array 12 taken along line I-I illustrated in FIG. 15A. In the microlens array 12, a plurality of microlenses is disposed in an array, and the microlens array 12 includes a plurality of lens portions 12A and a parallel plate portion 12B.

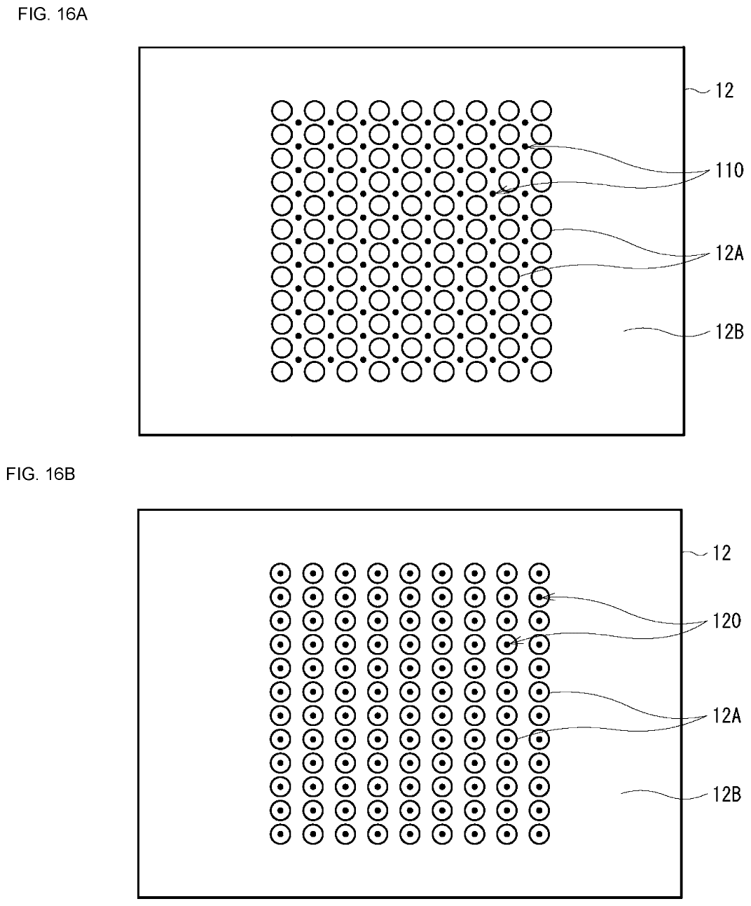

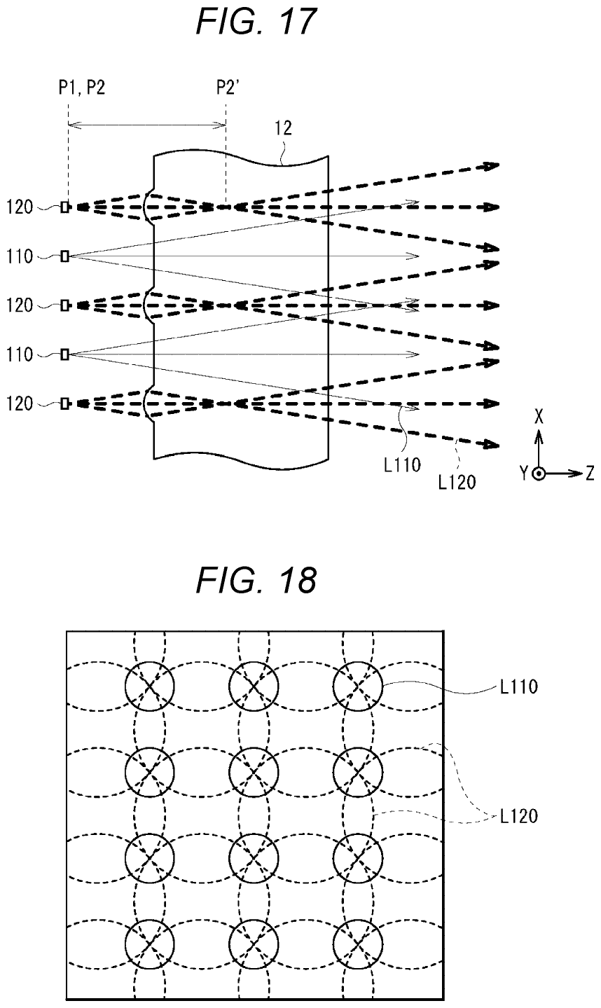

In Modification 4, as illustrated in FIG. 16A, the microlens array 12 is disposed such that a parallel plate portion 12B faces the plurality of light emission units 110 for spot irradiation. Furthermore, as illustrated in FIG. 16B, the lens portion 12A is arranged to face the plurality of light emission units 120 for uniform irradiation. Therefore, as illustrated in FIG. 17, each of the laser beams L120 emitted from the plurality of the light emission units 120 is refracted by a lens surface of each of the lens portions 12A, and for example, forms a virtual light emission point P2′ in the microlens array 12. That is, a light emission point P2 of each of the plurality of light emission units 120 at the same height as a light emission point P1 of each of the plurality of light emission units 110 is shifted in an optical axis direction (for example, in the Z-axis direction) of the light beams (the laser beams L110 and the laser beams L120) emitted from the plurality of light emission units 110 and the plurality of light emission units 120.

Therefore, by switching the light emission of the plurality of light emission units 110 and the plurality of light emission units 120, the laser beams L110 emitted from the plurality of light emission units 110 pass through the microlens array 12 as they are (without being refracted), and form a spot-shaped irradiation pattern as illustrated in FIG. 18, for example. Further, the laser beams L120 emitted from the plurality of light emission units 120 are refracted by the microlens array 12, and for example, as illustrated in FIG. 18, partially overlap the laser beams L120 emitted from the adjacent light emission units 120, thereby forming an irradiation pattern for irradiating a predetermined range with substantially uniform light intensity. In the illumination device 1, by switching between the light emission of the plurality of light emission units 110 and the light emission of the plurality of light emission units 120, it is possible to switch between spot irradiation and uniform irradiation.

Note that FIG. 17 illustrates an example in which the microlens array 12 functions as a relay lens, but the present technology is not limited thereto. For example, the virtual light emission point P2′ of the plurality of light emission units 120 may be formed between the light emission unit 120 and the microlens array 12.

The diffraction element 34 (an example of a third optical member) divides and emits the laser beams L110 emitted from the plurality of light emission units 110 and the laser beams L120 emitted from the plurality of light emission units 120. In Modification 4, for example, light is divided into five by the diffraction element 34. In this case, as illustrated in FIG. 3, a diffractive optical element (DOE) in which a fine lattice shape is formed on a plane of glass or the like can be used as the diffraction element 34. Therefore, the diffraction element 34 generates diffracted light in two directions with respect to the irradiation pattern of the diffraction element 14 described above.

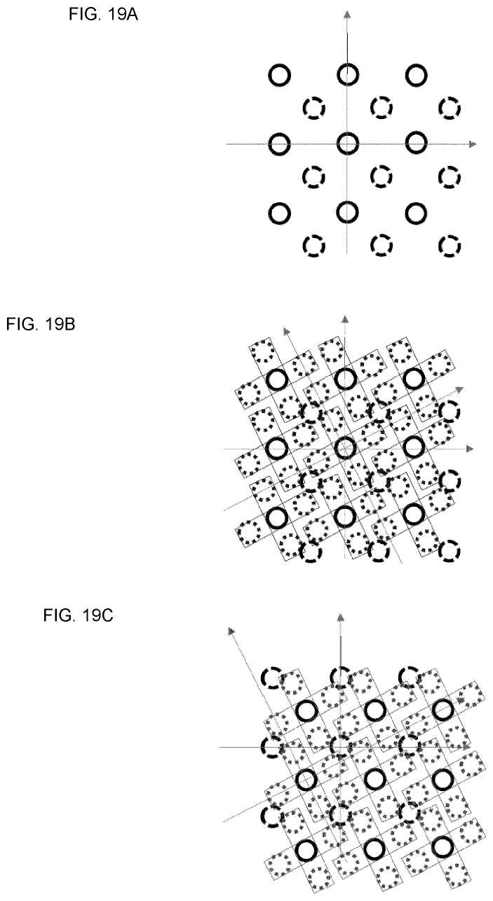

FIG. 19A illustrates an irradiation pattern of the laser beam L110 for spot irradiation which is transmitted through the diffraction element 34 as it is and emitted from the plurality of light emission units 110. FIG. 19A further illustrates the irradiation pattern of the laser beam L120 that is not yet subjected to beam forming. The irradiation pattern of the laser beam L110 is indicated by a solid line, and the irradiation pattern of the laser beam L120 is indicated by a dotted line.

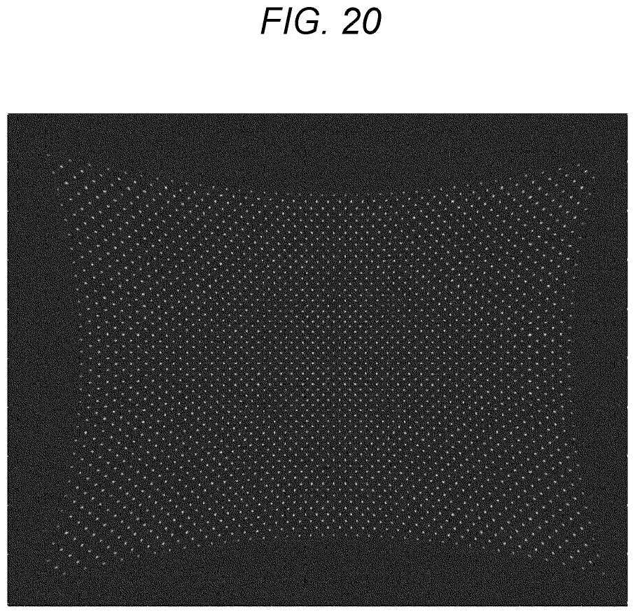

FIG. 19B illustrates an example in which the laser beam L120 is a laser beam for spot irradiation. As illustrated in FIG. 19B, by arranging the diffraction element 34, the 0th-order light of the laser beam L120 transmitted through the diffraction element 34 is emitted to the irradiation position of the laser beam L120 in a case where the diffraction element 34 is not arranged, and the +1st-order light and the −1st-order light diffracted by the diffraction element 34 are emitted to a position close to the 0th-order light. That is, by disposing the diffraction element 34, the number of light spots with which the irradiation target object 1000 is irradiated can be further increased. FIG. 20 is an irradiation pattern (corresponding to FIG. 19B) of the laser beams L120 emitted from the plurality of light emission units 120 and emitted to the irradiation target object 1000 in a case where the diffraction element 34 is disposed. By combining the laser beam L110 of FIG. 19A and the laser beam L120 of FIG. 19B, two sets of spot irradiation light can be switched and emitted.

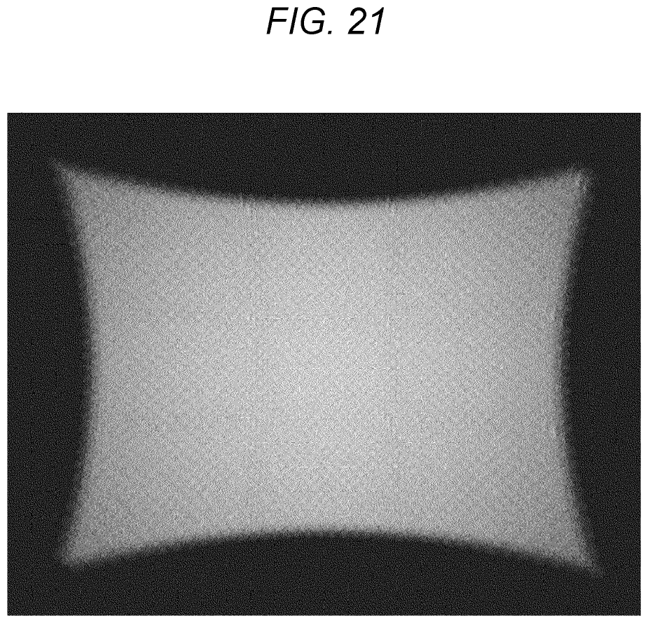

FIG. 19C illustrates an example in which the laser beam L120 is a laser beam for uniform irradiation. As illustrated in FIG. 19C, by arranging the diffraction element 34, the 0th-order light of the laser beam L120 transmitted through the diffraction element 34 is emitted to the irradiation position of the laser beam L120 in a case where the diffraction element 34 is not arranged, and the +1st-order light and the −1st-order light are emitted to a position close to the 0th-order light. FIG. 21 is an irradiation pattern (corresponding to FIG. 19C) of the laser beams L120 emitted from the plurality of light emission units 120 and emitted to the irradiation target object 1000 in a case where the diffraction element 34 is disposed. By combining the laser beam L110 of FIG. 19A and the laser beam L120 of FIG. 19C, it is possible to switch and emit light for spot irradiation and light for uniform irradiation. Since the laser beams L120 for uniform irradiation emitted from the plurality of light emission units 120 are diffracted, the uniformity of the light intensity at the time of uniform irradiation can be further improved by the overlapping of the diffracted light.

As described above, in the present modification, the diffraction element 34 is further arranged on the optical paths of the laser beams L110 and L120 respectively emitted from the plurality of light emission units 110 and the plurality of light emission units 120. As a result, as compared with the above embodiment and the like, by enabling uniform irradiation while having a spot irradiation function with a high light density with respect to the irradiation target object 1000, it is possible to measure the distance of the object at a short distance and with a higher resolution.

Note that, in the present modification, an example has been described in which the diffraction element 14 and the diffraction element 34 are configured as separate components, but the diffractive optical surface may be disposed to overlap both surfaces of one optical element or one surface of one optical surface. In addition, FIG. 14 illustrates an example in which the diffraction element 34 is arranged at the subsequent stage of the collimator lens 13, but the arrangement position of the diffraction element 34 is not limited thereto, and for example, may be arranged between the microlens array 12 and the collimator lens 13.

Furthermore, in the present modification, the diffraction element 34 may be integrated with the microlens array 12, for example. At that time, for example, it is possible to employ a configuration in which only the laser beam L110 for spot irradiation or only the laser beam L120 for uniform irradiation acts. Further, different diffraction patterns can be formed by the laser beam L110 for spot irradiation and the laser beam L120 for uniform irradiation.

As described in the above modification, the light beam emitted from the light emitting element is converted into a predetermined pattern by the optical unit. The optical unit has a configuration including one or a plurality of optical components, and includes, for example, at least one of the microlens array 12, the diffraction element 14, or the diffraction element 34.

### [Modification 5]

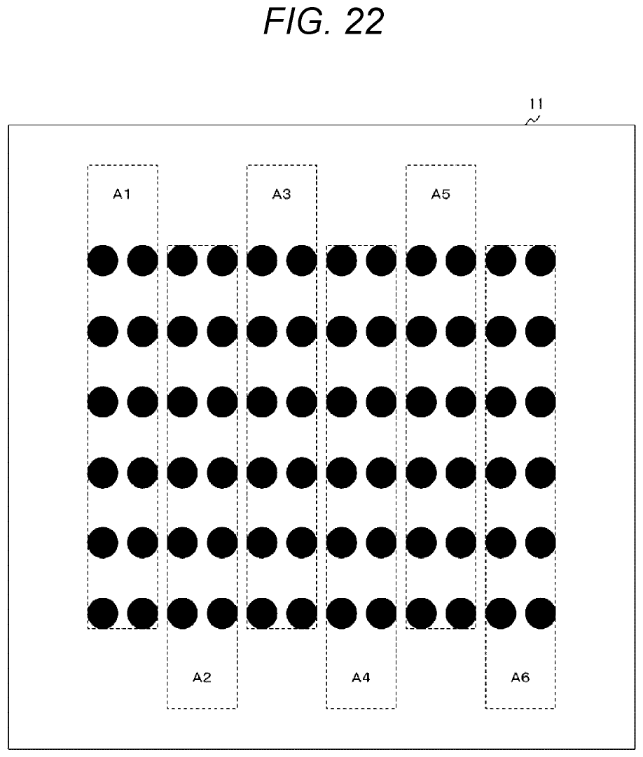

FIGS. 22 to 24 are diagrams illustrating examples of grouping of the light emitting elements 11 in Modification 5 of the present technology. In the embodiment, an example in which light emission of two sets of light emission units that perform spot irradiation is switched is described, and in Modification 4, for example, an example in which light emission of a light emission unit that performs spot irradiation and light emission of a light emission unit that performs uniform irradiation are switched is described, but the switching of the irradiation pattern is not limited to these examples. For example, the light emitting region may be switched according to the light emission switching control.

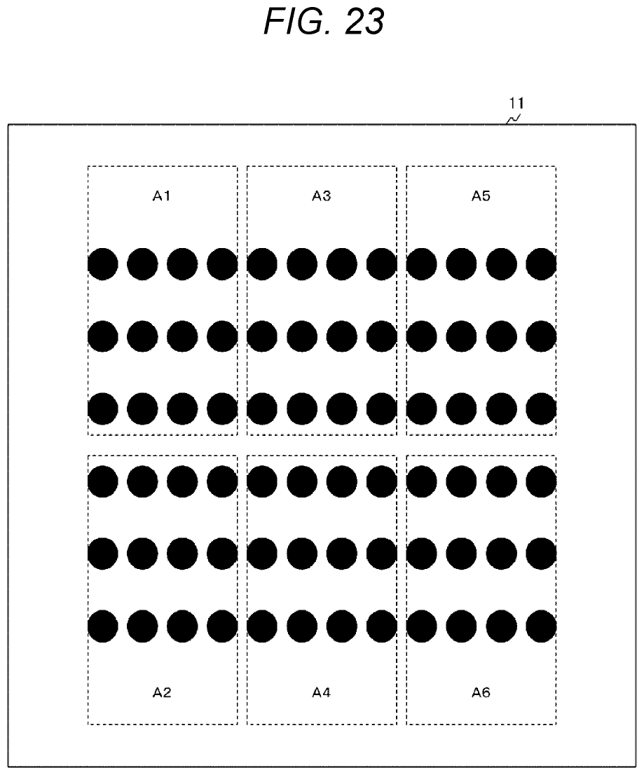

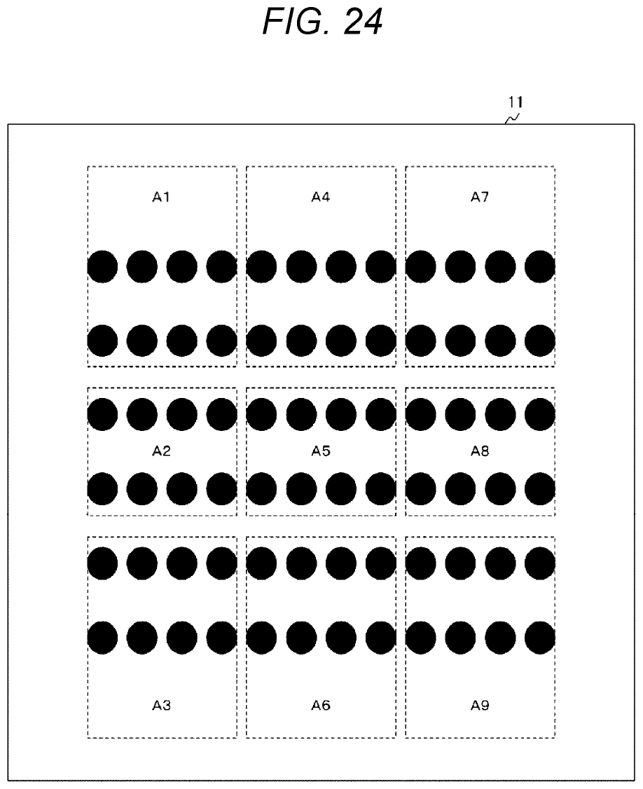

In the example in in FIG. 22, a case is assumed where one region is formed for every plurality of columns (two columns in this example) and switching is performed for each region. In the example in FIG. 23, a case is assumed where one frame is further vertically divided into two to form quadrangle regions and switching is performed for each region. In the example in FIG. 24, a case is assumed where one frame is vertically divided into three and switching is performed for each region.

When the number of spots is increased and light intensity per spot is maintained, there is a possibility that power consumption increases to exceed safety standard for protecting eyes. In this respect, by switching the light emission in units of light emission regions, flexible adjustment can be performed. Switching of light emission may be performed for each frame, and may be performed for each block or the like in the frame. Furthermore, it is also possible to recognize a position of a target object to be subjected to the distance measurement and allow the region to emit light.

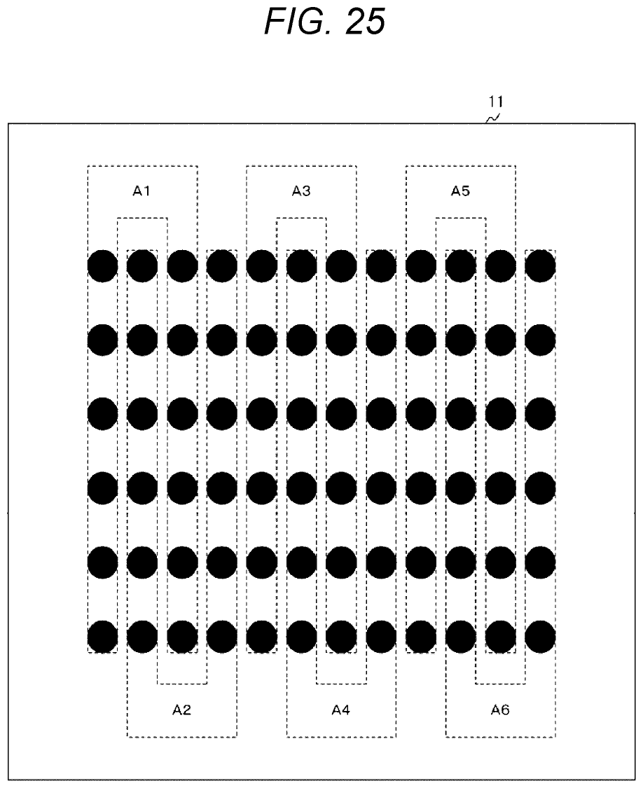

FIG. 25 is a diagram illustrating another example of grouping of the light emitting elements 11 according to a modification of the present technology. In this example, an example is illustrated in which grouping is performed for every two columns so that the light emitting elements 11 are differently combined for every columns. For example, first and third columns form a region A1, second and fourth columns form a region A2, fifth and seventh columns form a region A3, sixth and eighth columns form a region A4, ninth and 11th columns form a region A5, and 10th and 12th columns form a region A6. Therefore, switching of light emission may be controlled for every two columns. Therefore, it is possible to reduce power consumption caused by region switching and increase light output within the laser safety standard while taking multipath countermeasures.

Note that light emission switching control different from the light emission switching control described in the embodiment and the modification may be performed on the light emitting element. For example, light emission switching control of switching the light emission unit for spot irradiation and the light emission unit for uniform irradiation described in Modification 4 for each region as described in Modification 5 may be performed.

### [Modification 6]

In the above-described embodiment, an example in which each of the light emission units 110 and 120 is separated by a mesa structure having a columnar mesa portion has been described, but the present invention is not limited thereto. For example, the light emission unit 110 and the light emission unit 120 may be in one structure, and the light emission units may be separated by the current confinement region 148B of the current confinement layer 148 (by current confinement). In this manner, the light emission units 110 and 120 may be separated by a separation structure having no mesa structure.

### 3. Application Example

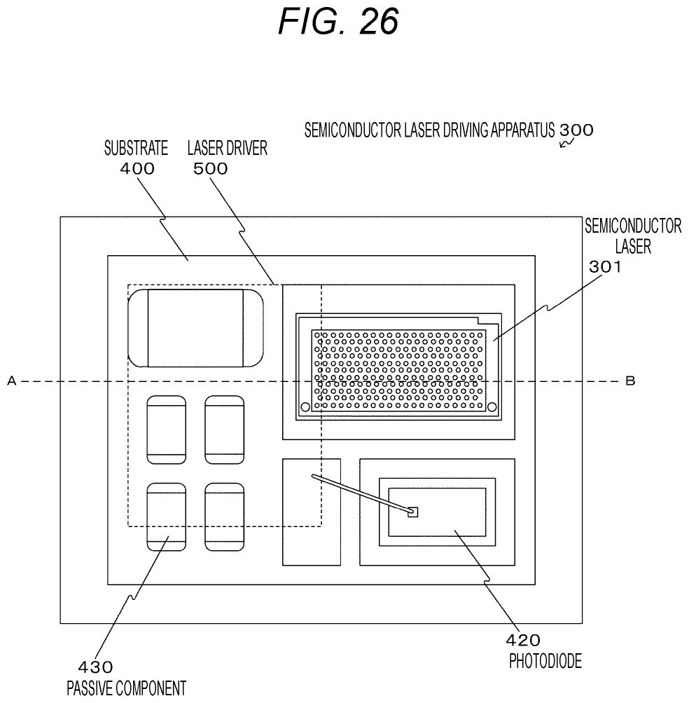

Next, application examples of the present technology will be described. In the present application example, the present technology is configured as a semiconductor laser driving apparatus 300. FIG. 26 is a diagram illustrating an example of a top view of the semiconductor laser driving apparatus 300 in an application example of the present technology. The semiconductor laser driving apparatus 300 is assumed to measure a distance by TOF. TOF has a feature of high depth accuracy, which is not as high as structured light, and of being able to operate without problems even in a dark environment. In addition, it is considered that there are many advantages in terms of simplicity of a device configuration, cost, and the like as compared with other methods such as a structured light and a stereo camera.

In the semiconductor laser driving apparatus 300, a semiconductor laser 301, a photodiode 420, and a passive component 430 are electrically connected and mounted by wire bonding on the surface of a substrate 400 incorporating a laser driver 500 (an example of a driving element). As the substrate 400, a printed wiring board is assumed. Here, the above-described illumination devices 1 and 1B can be applied to the semiconductor laser 301, and for example, the light receiving unit 210 in FIG. 1 can be applied as the photodiode 420.

The semiconductor laser 301 is a semiconductor device that emits a laser light by causing a current to flow through a PN junction of a compound semiconductor. Here, as the compound semiconductor to be used, for example, aluminum gallium arsenide (AlGaAs), indium gallium arsenide phosphorus (InGaAsP), aluminum gallium indium phosphorus (AlGaInP), gallium nitride (GaN), and the like are assumed.

The laser driver 500 is a driver integrated circuit (IC) for driving the semiconductor laser 301. The laser driver 500 is built in the substrate 400 in a face-up state. Since it is necessary to reduce the wiring inductance for electrical connection with the semiconductor laser 301, the wiring length is desirably as short as possible.

The photodiode 420 is a diode for detecting light. The photodiode 420 is used for automatic power control (APC) for monitoring the light intensity of the semiconductor laser 301 and maintaining the output of the semiconductor laser 301 constant.

The passive component 430 is a circuit component other than an active element such as a capacitor and a resistor. The passive component 430 includes a decoupling capacitor for driving the semiconductor laser 301.

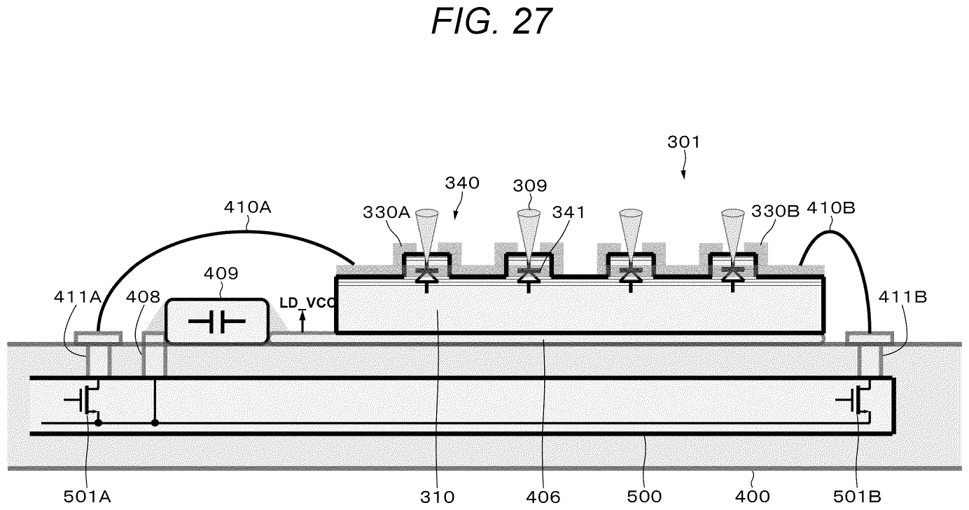

FIG. 27 is a diagram illustrating an example of a cross-sectional view of the semiconductor laser driving apparatus 300 in an application example of the present technology. As described above, the substrate 400 incorporates the laser driver 500, and the semiconductor laser 301 and the like are mounted on the surface thereof. Connection between the semiconductor laser 301 and laser drivers 501A and 501B in the substrate 400 is performed via connection vias 411A and 411B. By using the connection vias 411A and 411B, the wiring length can be shortened.

The semiconductor laser 301 is assumed to be a vertical cavity surface emitting laser. The VCSEL has a substrate 310 as a substrate material, and a common anode is provided therebelow. The light emission points are formed as trapezoidal mesas 340, each including a light emitting element 341.

The anode electrode of the light emitting element 341 is connected to a pattern 406 of signal lines on the substrate 400 via a connection layer (not illustrated). A cathode electrode of the light emitting element is connected to metal layers 330A and 330B, and one ends of driver elements 501A and 501B are connected to the metal layers 330A and 330B via wire bonding 410A and 410B. Here, the connection layer can be constituted by either silver paste or solder. The wire bonding 410A and 410B and the driver elements 510A and 510B are connected by connection vias 411A and 411B.

In addition, in the application example, since the light emission point of the semiconductor laser 301 is located immediately above the substrate 400, heat generated at the light emission point can be efficiently released to the component built-in substrate.

Further, the substrate 400 includes a thermal via for heat dissipation. Each component mounted on the substrate 400 is a heat source, and the heat generated in each component can be dissipated from the back surface of the substrate 400 by using the thermal vias.

As illustrated in FIG. 27, in the present application example, a capacitance 409 is mounted as a decoupling capacitor on a substrate 400, and is connected between the pattern 406 and a ground (GND) 408. Since the capacitance 409 is provided as a decoupling capacitor, the charge stored in the capacitance 409 can be used as a drive current of the semiconductor laser 301. As described above, according to the application example, when the laser is modulated at high speed, the charge stored in the capacitance 409 mounted most recently of the semiconductor laser 301 becomes the drive current of the semiconductor laser 301, so that it is possible to realize higher speed modulation.

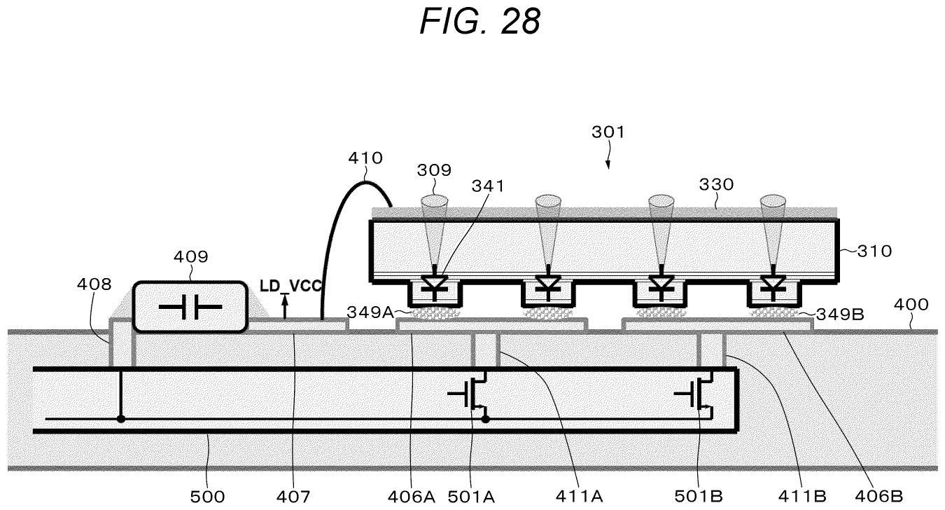

As illustrated in FIG. 28, the front and back surfaces of the light emitting element 341 may be disposed in opposite directions. In this case, emitted light 309 from the light emitting element 341 is emitted through the substrate 310. The cathode of the light emitting element 341 is connected to the patterns 406A and 406B of the signal lines on the substrate 400 via bumps 349A and 349B, and is connected to one end of the driver elements 501A and 501B of the laser driver 500 built in the substrate 400 via the connection vias 411A and 411B. The other ends of the driver elements 501A and 501B are connected to the ground (GND) 408. As an anode electrode of the light emitting element 341, a metal layer 330 is provided on the light emission side surface of the substrate 310, and is connected to a power supply pattern 407 of the substrate 400 via wire bonding 410. Here, the metal layer 330 may be a transparent electrode such as indium tin oxide (ITO). The side of the light emitting element 341 other than the light emission side is connected to the driver elements 501A and 501B via the bump 349, the patterns 406A and 406B, and the connection vias 411A and 411B. Here, the bumps 349A and 349B can be constituted by any of gold (Au), copper (Cu), or solder.

Note that, the above embodiments illustrate examples for embodying the present technology, and matters in the embodiments and matters specifying the invention in claims have correspondence relationships. Similarly, the matters specifying the invention in the claims and matters having the same names in the embodiments of the present technology have correspondence relationships. However, the present technology is not limited to the embodiments and can be embodied by making various modifications to the embodiments without departing from the gist thereof.

Note that effects described in the present specification are merely examples and are not limited, and other effects may be provided.

Note that the present technology may also have a following configuration.

(1)

A light emitting element including:
a conductive substrate having a first main surface and a second main surface opposite to the first main surface;
a first electrode provided on the first main surface of the conductive substrate;
a first DBR layer provided on a side of the second main surface of the conductive substrate and having a first main surface;
at least two light emission units provided on a side opposite to the first main surface of the first DBR layer,
in which a tunnel junction layer is provided between the second main surface of the conductive substrate and the first main surface of the first DBR layer, and
each of the light emission units is separated from each other;
a second DBR layer laminated on the first DBR layer and having a first main surface and a second main surface opposite to the first main surface; and
a second electrode provided on a side of the second main surface of the second DBR layer.

(2)

The light emitting element according to (1),
in which the first DBR layer includes a p-type DBR layer.

(3)

The light emitting element according to (2),
in which the second DBR layer includes an n-type DBR layer.

(4)

The light emitting element according to (2),
in which the second DBR layer includes a p-type DBR layer, and
another tunnel junction layer different from the tunnel junction layer is further provided between the first main surface of the second DBR layer and the first DBR layer.

(5)

The light emitting element according to (1),
in which an n-type DBR layer is further provided between the conductive substrate and the tunnel junction layer.

(6)

The light emitting element according to any one of (1) to (5),
in which the conductive substrate is an n-type substrate.

(7)

A light emitting element including:
a conductive substrate having a first main surface and a second main surface opposite to the first main surface;
a first electrode provided on the first main surface of the conductive substrate;
a first n-type DBR layer provided on a side of the second main surface of the conductive substrate and having a first main surface;
at least two light emission units provided on an opposite side to the first main surface of the first n-type DBR layer, each of the light emission units being separated from each other;
a second n-type DBR layer having a first main surface and a second main surface opposite to the first main surface;
a tunnel junction layer; and
a second electrode provided on a side of the second main surface of the n-type DBR layer, in which the tunnel junction layer is provided between the opposite side of the first n-type DBR layer and the second main surface of the second n-type DBR layer.

(8)

An illumination device including:
a light emitting element according to any one of (1) to (7);
a holding unit that holds the light emitting element; and
an optical unit that converts a light beam emitted from the light emitting element into a predetermined pattern.

(9)

The illumination device according to (8),
in which a light emission pattern is switched according to light emission switching control for the light emitting element.

(10)

The illumination device according to (9),
in which the light emission switching control switches between a spot irradiation pattern and a uniform irradiation pattern.

(11)

The illumination device according to (9),
in which a light emitting region is switched according to light emission switching control of the light emitting element.

(12)

The illumination device according to (9), further including:
the light emitting element;
a first optical member that emits a plurality of first light emitted from a plurality of the first light emission unit and a plurality of second light emitted from a plurality of the second light emission unit in substantially parallel to each other;
a second optical member that shapes a beam shape of at least one of the plurality of first light or the plurality of second light, and emits the plurality of first light and the plurality of second light as light having different beam shapes; and
a third optical member that is disposed on optical paths of the plurality of first light and the plurality of second light, refracts or diffracts the plurality of first light to increase the number of spots with which an irradiation target object is irradiated, and refracts or diffracts the plurality of second light to increase an overlapping range with the second light emitted from the second light emission units adjacent,
in which the plurality of first light emitted from the plurality of first light emission units is emitted to the irradiation target object in a spot-shaped pattern, and
the plurality of second light emitted from the plurality of second light emission units is emitted to the irradiation target object with a predetermined range in a substantially uniform pattern while being partially overlapped on the second light emitted from the second light emission unit adjacent.

(13)

A distance measuring device including:
an illumination device according to any one of (8) to (12);
a control unit that controls the illumination device;
a light receiving unit that receives reflected light reflected from a target object; and
a distance measuring unit that calculates a distance measurement distance from image data obtained by the light receiving unit.

### REFERENCE SIGNS LIST

1 Illumination device
11 Light emitting element
23 Anode electrode
24, 25 Cathode electrode
100 Distance measuring device
130 n-type substrate
141 n-type DBR layer
145 p-type DBR layer
143 Active layer
160 Tunnel junction layer
210 Light receiving unit
220 Control unit
230 Distance measuring unit
300 Semiconductor laser driving apparatus
409 Capacitor
1000 Irradiation target object

1. A light emitting element comprising:
a conductive substrate having a first main surface and a second main surface opposite to the first main surface;
a first electrode provided on the first main surface of the conductive substrate;
a first DBR layer provided on a side of the second main surface of the conductive substrate and having a first main surface;
at least two light emission units provided on a side opposite to the first main surface of the first DBR layer,
wherein a tunnel junction layer is provided between the second main surface of the conductive substrate and the first main surface of the first DBR layer, and
each of the light emission units is separated from each other;
a second DBR layer laminated on the first DBR layer and having a first main surface and a second main surface opposite to the first main surface; and
a second electrode provided on a side of the second main surface of the second DBR layer.

2. The light emitting element according to claim 1,
wherein the first DBR layer includes a p-type DBR layer.

3. The light emitting element according to claim 2,
wherein the second DBR layer includes an n-type DBR layer.

4. The light emitting element according to claim 2,
wherein the second DBR layer includes a p-type DBR layer, and
another tunnel junction layer different from the tunnel junction layer is further provided between the first main surface of the second DBR layer and the first DBR layer.

5. The light emitting element according to claim 1,
wherein an n-type DBR layer is further provided between the conductive substrate and the tunnel junction layer.

6. The light emitting element according to claim 1,
wherein the conductive substrate is an n-type substrate.

7. A light emitting element comprising:
a conductive substrate having a first main surface and a second main surface opposite to the first main surface;
a first electrode provided on the first main surface of the conductive substrate;
a first n-type DBR layer provided on a side of the second main surface of the conductive substrate and having a first main surface;
at least two light emission units provided on an opposite side to the first main surface of the first n-type DBR layer,
each of the light emission units being separated from each other;
a second n-type DBR layer having a first main surface and a second main surface opposite to the first main surface;
a tunnel junction layer; and
a second electrode provided on a side of the second main surface of the n-type DBR layer,
wherein the tunnel junction layer is provided between the opposite side of the first n-type DBR layer and the second main surface of the second n-type DBR layer.

8. An illumination device comprising:
the light emitting element according to claim 1;
a holding unit that holds the light emitting element; and
an optical unit that converts a light beam emitted from the light emitting element into a predetermined pattern.

9. The illumination device according to claim 8,
wherein a light emission pattern is switched according to light emission switching control for the light emitting element.

10. The illumination device according to claim 9,
wherein the light emission switching control switches between a spot irradiation pattern and a uniform irradiation pattern.

11. The illumination device according to claim 9,
wherein a light emitting region is switched according to light emission switching control of the light emitting element.

12. The illumination device according to claim 10,
the light emitting element including a first light emission unit and a second light emission unit,
the illumination device further comprising:
a first optical member that emits a plurality of first light emitted from a plurality of the first light emission unit and a plurality of second light emitted from a plurality of the second light emission unit in substantially parallel to each other;
a second optical member that shapes a beam shape of at least one of the plurality of first light or the plurality of second light, and emits the plurality of first light and the plurality of second light as light having different beam shapes; and
a third optical member that is disposed on optical paths of the plurality of first light and the plurality of second light, refracts or diffracts the plurality of first light to increase the number of spots with which an irradiation target object is irradiated, and refracts or diffracts the plurality of second light to increase an overlapping range with the second light emitted from the second light emission units adjacent,
wherein the plurality of first light emitted from the plurality of first light emission units is emitted to the irradiation target object in the spot irradiation pattern, and
the plurality of second light emitted from the plurality of second light emission units is emitted to the irradiation target object with a predetermined range in the uniform irradiation pattern while being partially overlapped on the second light emitted from the second light emission unit adjacent.

13. A distance measuring device comprising:
the illumination device according to claim 8;
a control unit that controls the illumination device;
a light receiving unit that receives reflected light reflected from a target object; and
a distance measuring unit that calculates a distance measurement distance from image data obtained by the light receiving unit.
